(19) United States
(12) Patent Application Publication
(10) Pub. No.: US 2012/0139627 A1
(43) Pub. Date: Jun. 7, 2012

(54) METHOD FOR USING AN AMPLIFIER

(76) Inventor: Mats Carlsson, Sundyberg (SE)

(21) Appl. No.: 13/127,754

(22) PCT Filed: Apr. 23, 2011
(86) PCT No.: PCT/US11/33700

§ 371 Date: May 5, 2011

Related U.S. Application Data
(60) Provisional application No. 61/332,211, filed on May 7, 2010.

(51) Int. Cl. H03F 1/00

(52) U.S. Cl. 330/103

(57) ABSTRACT

An amplifier is provided that has a first loop interacting with a second loop. A feedback signal and input signal are provided to the amplifier. The first loop and the second loop interact with the input signal to nullify the feedback signal.

### TECHNICAL FIELD

The invention relates to a method for using an amplifier such as a low-noise amplifier having two interacting feedback loops.

### BACKGROUND OF INVENTION

Amplifiers such as low-noise amplifiers are widely used. Many low-noise amplifiers are used to amplify input signals which may be represented by one of the electrical properties: current, voltage or power. The input signal is often small in magnitude and is required to be amplified to be able to further process the signal. To avoid that the small signal is drowned in undesirable noise, a small noise contribution of the amplifier is required to overcome such noise in the low noise amplifier.

In many low-noise amplifiers, it is desirable to have a known gain. This gain can be fixed or variable. It is also often desirable to have known and fixed input impedance, especially in amplifiers used for high frequency applications (such as frequencies above 1 GHz) due to the need for having an input impedance that is as similar as possible to the complex conjugate of the source impedance. The desired input signal of the amplifier is often superimposed on top of larger unwanted signals. The input signal has also often a large dynamic range i.e. the signal can in some situations be weak but strong in other situations.

A conventional amplifier is therefore often dimensioned in such way that the largest possible input signals can be handled by the amplifier. One important parameter, that must be dimensioned large enough to handle the largest input signals, is the bias current used in the amplifier. However, when the input signal is not strong, the bias current in the amplifier is often unnecessarily large and the bias current is thus not fully utilized. For example, in battery driven applications, it is important to keep the current consumption at a minimum to increase battery life time.

Because conventional low-noise amplifiers largely depend upon the absolute values of many parameters such as the capacitance and trans-conductance of the input stage, the inductance value, the quality factor of the inductance, the load resistor and the bias current of the input stage, the performance of the design is sensitive to the spread or variations of these parameters. This means the various parameters must be balanced or optimized which may be difficult to accomplish. Also, conventional low-noise amplifiers using inductors can only be optimized in a narrow frequency band and in a narrow bias current interval since the inductances must resonate with the capacitances in the design. Thus, conventional amplifiers are quite sensitive to changes of the parameters listed above. Another problem is that conventional high frequency amplifiers require many inductors which may make the topology large.

Various feedback techniques have been used to try to solve the above-outlined problems. However, feedback is however not easy to effectively use in high frequency applications (frequencies above a couple of 100 MHz), due to the difficulties in obtaining a high enough loop gain while maintaining a design that is stable and does not oscillate. There is a need to provide a more effective amplifier topology that does not have the drawbacks outlined above.

### SUMMARY OF INVENTION

The method of the present invention provides a solution to the above-outlined problems. More particularly, the method relates to using an amplifier that has a first loop interacting with a second loop. A feedback signal and an input signal are provided to the amplifier. The first loop and the second loop interact to nullify the feedback signal. The transfer functions of the amplifier are substantially independent of the bias currents and the amplifier of the present invention is suitable for high frequency applications.

### BRIEF DESCRIPTION OF DRAWINGS

FIG. 1 is a prior art low-noise amplifier;

FIG. 2 is a schematic illustration of a low-noise amplifier topology according to the present invention;

FIG. 3 is a schematic view of gain and impedance plotted as a function of gm;

FIG. 4 is a schematic view of loop gains plotted as a function of gm;

FIG. 5 is a schematic view of loop gains plotted as a function of resistor R3; and

FIG. 6 is a schematic illustration of a two-stage amplifier topology of the present invention.

### DETAILED DESCRIPTION

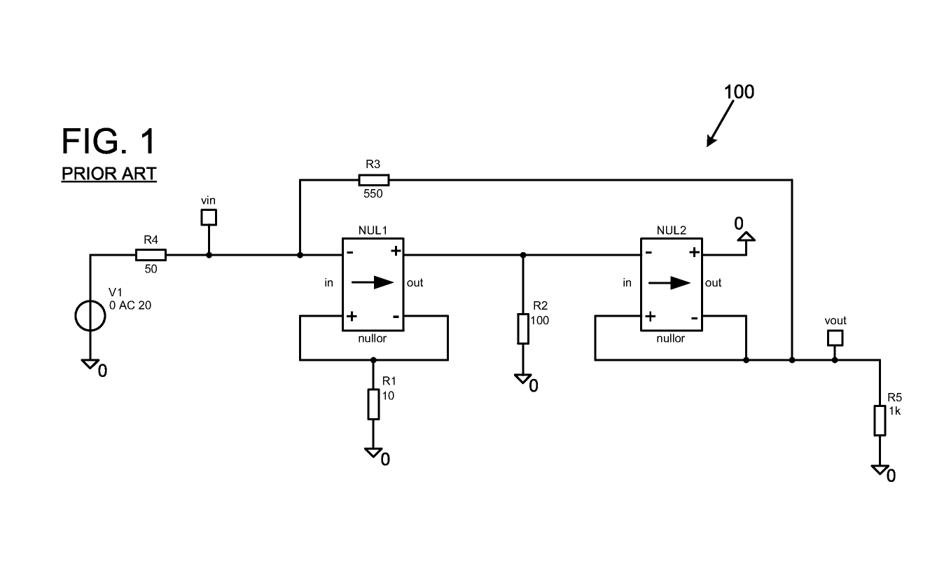

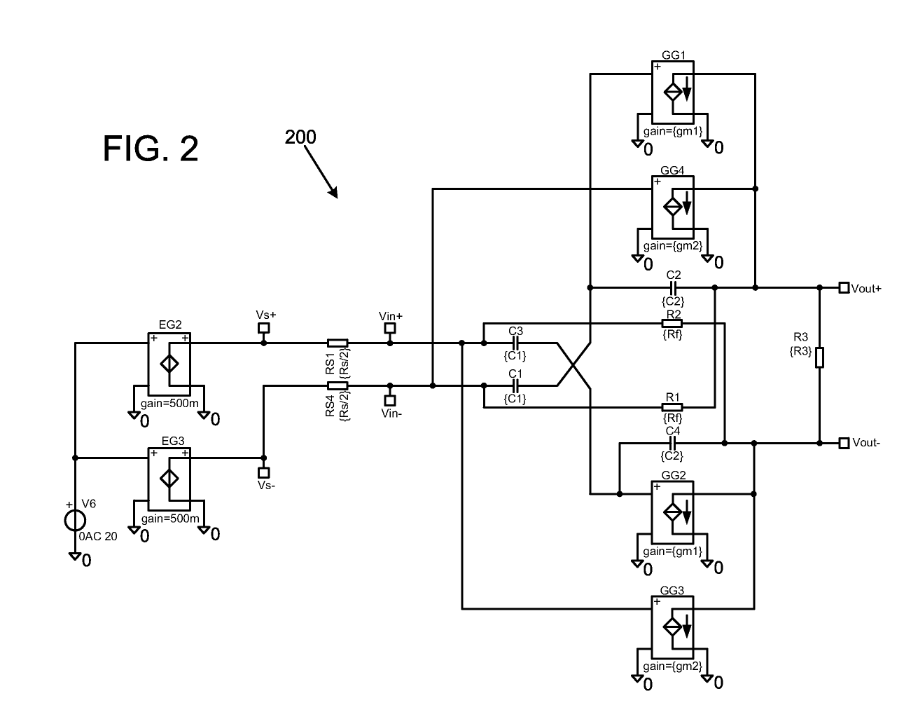

With reference to FIG. 1, a prior art low-noise amplifier topology 100 is depicted. The amplifier topology 100 is built with ideal amplifiers with infinite gain so that the transfer function or voltage gain may be described as Aᵥ=vₒᵤₜ/vᵢₙ=R2/R1. The input impedance may be described as Zᵢₙ=R3/(Aᵥ+1). These equations require a relatively high loop gain to be valid and the amplifier topology cannot effectively be used for high frequencies, such as frequencies above 1 GHz. The feedback network of the amplifier topology 100 basically consists of resistors R1 and R3. When a current flows through resistor R3 the current makes sure that the negative input of the first amplifier (NUL1) becomes exactly the same as the positive input of the input amplifier. One problem with the amplifier topology 100 is that the input voltage Vᵢₙ of the first amplifier (NUL1) goes to zero only when the loop gain approaches infinity. In other words, the feedback when the loop gain is high zeros out the input voltage of the amplifier. A high loop gain often results in an amplifier that is not stable and it may oscillate in an undesirable way. The low-noise amplifier topology 200 of the present invention is shown in FIG. 2. In general, the amplifier 200 uses feedback to produce a fixed and well-defined gain and input impedance. The gain depends therefore only on the ratio between parameters which varies in the same direction. For example, if a value of a first capacitance C1 goes up the equivalent value of a second capacitance C2 is likely going up also at an equivalent amount. This ratio is illustrated in equation (3) discussed in detail below so the ratio between the two parameters remains about the same and the amplification A is relatively constant. This is in contrast to conventional amplifiers that are dependent upon a wide variety of very different parameters and the behavior of the actual amplification is not even close to being constant when the parameters vary. This makes the amplifier 200 insensitive to the spread in technology parameters and temperature variations. The feedback may be implemented with two loops that operate together to achieve the desired transfer function.

One important feature is that the loop gain in each loop does not have to be large to achieve the desired transfer function and permits the approximation without too much error since the two loops cooperate which enables use at high frequencies. In general, the loop gain in the first loop is affected by and dependent on the second loop. A first loop may extend from the output of gm1 (GG1) to Vₒᵤₜ₊ and via capacitance C2 and the node disposed between capacitance C1 and the plus side of the input of gm1 (GG1). The first loop then extends to the plus side of gm1 (GG1). A second loop may extend from the output of gm2 (GG4) to Vₒᵤₜ₊ and via resistor R1, the node next to Vᵢₙ₋ back to the plus side of gm2 (GG4). An important aspect to this two loop amplifier concept is that the two gm stages (GG1 and GG4) can be considered as one differential amplifier with an input which should be nullified due to the feedback network and high loop gain. Since the input of GG4 is connected to the negative input of the amplifier (Vin−), the differential input can be nullified without large loop-gain. This cooperation between the first and second loops makes it easier to get the amplifier 200 stable and hence possible to use at high frequencies. Furthermore, the amplifier 200 does not require inductances to be tuned with parasitic capacitances which make it possible to operate over a large frequency range, hence wide-band operation.

A very important feature of the present invention is that the transfer functions (input impedance and gain) of the amplifier 200 are almost independent of the bias currents in the amplifiers (GG1-GG4). This makes it possible to adjust the bias currents in the amplifier 200 to avoid waist of excessive current when the signal conditions are such that large currents are not required. In this way, the bias current can be made dynamically adjustable depending on the signal conditions. As indicated above, in conventional amplifiers, such dynamic adjustment of the bias currents is not possible since it will drastically change the transfer functions of the conventional amplifiers.

As best shown in FIG. 2, the input of the amplifier topology 200 may be described as the differential voltage between the nodes Vᵢₙ₊ and Vᵢₙ₋ so that Vᵢₙ=Vᵢₙ₊−Vᵢₙ₋. The input may be driven by a differential source-impedance Rs which may be equally distributed in the resistors RS1 and RS4. Similarly, the output of the amplifier 200 may be described as the differential voltage between the nodes Vₒᵤₜ₊ and Vₒᵤₜ₋, so that Vₒᵤₜ=Vₒᵤₜ₊−Vₒᵤₜ₋. The active components of the amplifier 200 are preferably implemented as trans-conductance amplifiers, each with a trans-conductance of gm1 and gm2. The trans-conductance may be depicted as four single-ended amplifiers. However, these amplifiers can also be implemented as differential stages. The load of the amplifier 200 is defined by the resistor R3.

The transfer functions of the amplifier 200 can be calculated. In equation (1) below, the voltage gain is denoted Aᵥ and in equation (2) below, the input impedance is denoted Rᵢ. The parameter Cᵢ may be defined as the value of the capacitances C1 and C3, the parameter C₂ as the value of the capacitances C2 and C4 and the parameter R_{f} as the value of the resistors R1 and R2.

$$\begin{matrix}{A}_{v} = \frac{\frac{{R}_{3}}{2} ( {g}_{m 1} \frac{{C}_{1}}{{C}_{1} + {C}_{2}} + {g}_{m 2} - \frac{1}{{R}_{f}} )}{1 + \frac{{R}_{3}}{2} ( {g}_{m 1} \frac{{C}_{2}}{{C}_{1} + {C}_{2}} + \frac{1}{{R}_{f}} )} & Equation ( 1 ) \\ {R}_{i} = \frac{2 {R}_{1}}{1 + {A}_{V}} & Equation ( 2 )\end{matrix}$$

When the parameter related to the feedback resistor R_{f} can be assumed to be small compared with the other parameters within the brackets of both the nominator and the denominator and when the parameter of the denominator which is proportional to R₃ can be assumed much larger than 1, the expression for the gain can surprisingly be simplified into the expression as shown in equation (3) below.

$${A}_{v} \approx \frac{{C}_{1}}{{C}_{2}} + \frac{{g}_{m 2}}{{g}_{m 1}} \cdot \frac{{C}_{1} + {C}_{2}}{{C}_{2}} \qquad Equation ( 3 )$$

As shown in equation (3), the gain may be described as only being dependant on the ratios between capacitances Cᵢ and C₂ and trans-conductances gₘ₁ and gₘ₂. Trans-conductances (gₘ₁ and gₘ₂) are dependant on bias currents, but since the expression on equation depends on the ratio of the trans-conductances, the gain may become independent of the bias currents. An important realization is that the trans-conductance and capacitance vary in the same direction in integrated circuits. The gain of the amplifier 200 therefore does not vary even if the absolute values would vary. Hence, since the gain is well defined and fixed, the input impedance Rᵢ is also well defined.

The capacitances which define the gain transfer function can be replaced by any impedance without changing the conceptual idea of the present invention. Since the gain is mostly defined by the capacitance ratios, which has no noise contribution, the noise performance of the amplifier 200 is superior which is desirable in low noise amplifiers.

As best shown in FIG. 2, there are at least two different feedback loops from the output to the input. To make sure that the amplifier 200 is stable, it is desirable that the phase shift in these loops is not too large when the loop gain is higher than 1. The loop gain of these two loops can be calculated as shown in equations (4) and (5) below:

$$\begin{matrix}A {β}_{01} = \frac{R 3 \frac{{g}_{m 1}}{2} ( 1 + \frac{2 {R}_{f}}{{R}_{S}} \frac{{C}_{2}}{{C}_{1} + {C}_{2}} )}{\frac{R 3}{{R}_{S}} + R 3 \frac{{g}_{m 2}}{2} + 1 + \frac{2 {R}_{f}}{{R}_{S}}} & Equation ( 4 ) \\ A {β}_{02} = \frac{R 3 \frac{{g}_{m 2}}{2}}{\frac{R 3}{{R}_{S}} + R 3 \frac{{g}_{m 1}}{2} ( 1 + \frac{2 {R}_{f}}{{R}_{S}} \frac{{C}_{2}}{{C}_{1} + {C}_{2}} ) + 1 + \frac{2 {R}_{f}}{{R}_{S}}} & Equation ( 5 )\end{matrix}$$

When the parameters in equations (4) and (5) are provided with realistic values, the loop gain is surprisingly much smaller compared to conventional feedback amplifiers that have only one loop. This makes it much easier to ensure stability and hence make it possible to use feedback also at higher frequencies.

Table 1 below shows realistic values of the parameters in a typical implementation of the amplifier 200 shown in FIG. 2.

TABLE (1)

| | Unit | Value |
|---|---|---|
| gₘ₁ | [mS] | 100 |
| gₘ₂ | [mS] | 100 |
| R_{f} | [kohm] | 1.1 |
| R₃ | [kohm] | 3 |
| C₁ | [pF] | 1 |
| C₂ | [pF] | 0.1 |
| Rₛ | [kohm] | 0.1 |

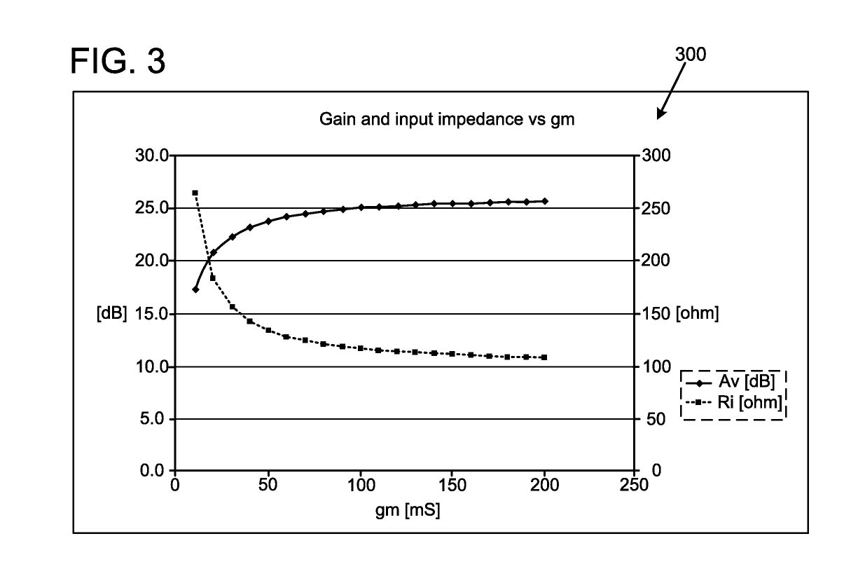

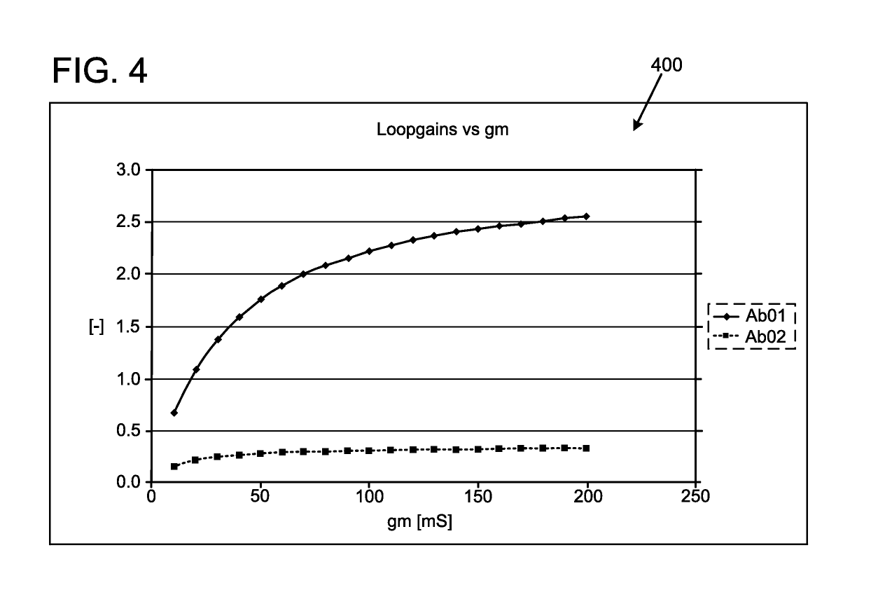

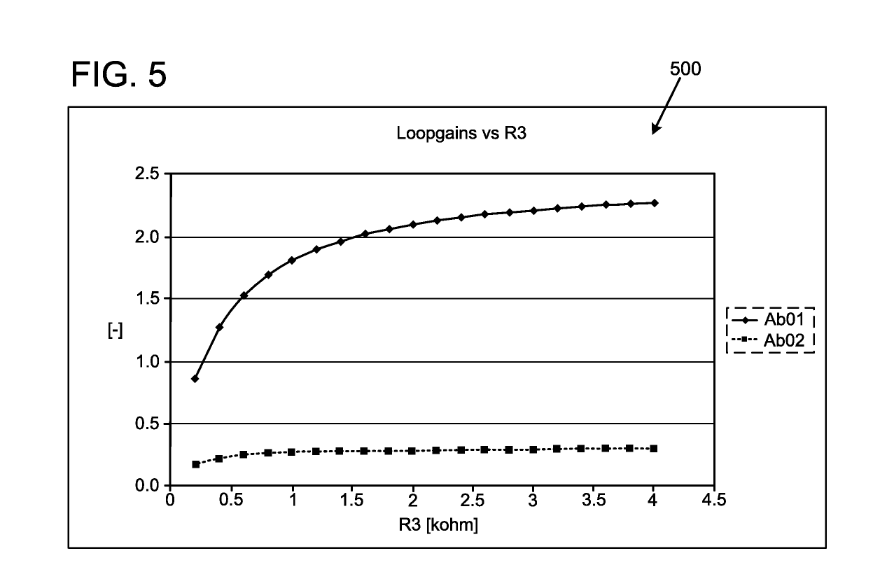

FIG. 3 shows transfer functions of the amplifier 200 in a chart 300 related to the gain Aᵥ and the input impedance Rᵢ plotted as a function of trans-conductance gm using the parameter values of Table 1. FIG. 4 shows loop gains A_{b01} and A_{b02} of the amplifier 200 in a chart 400 plotted as a function of trans-conductance gm using the parameter values of Table 1. FIG. 4 shows that the transfer functions of the amplifier 200 is fairly constant for trans-conductances above 50-70 mS, while the loop gain is below one in one of the loops and marginally above one in the other loop. Similarly, FIG. 5 shows loop gains A_{b01} and A_{b02} of the amplifier 200 in a chart 500 plotted as a function of the load resistor R3 using the parameter values of Table 1. Both FIGS. 4-5 show that the loop gain is quite insignificant i.e. below a value of 2.5-3.

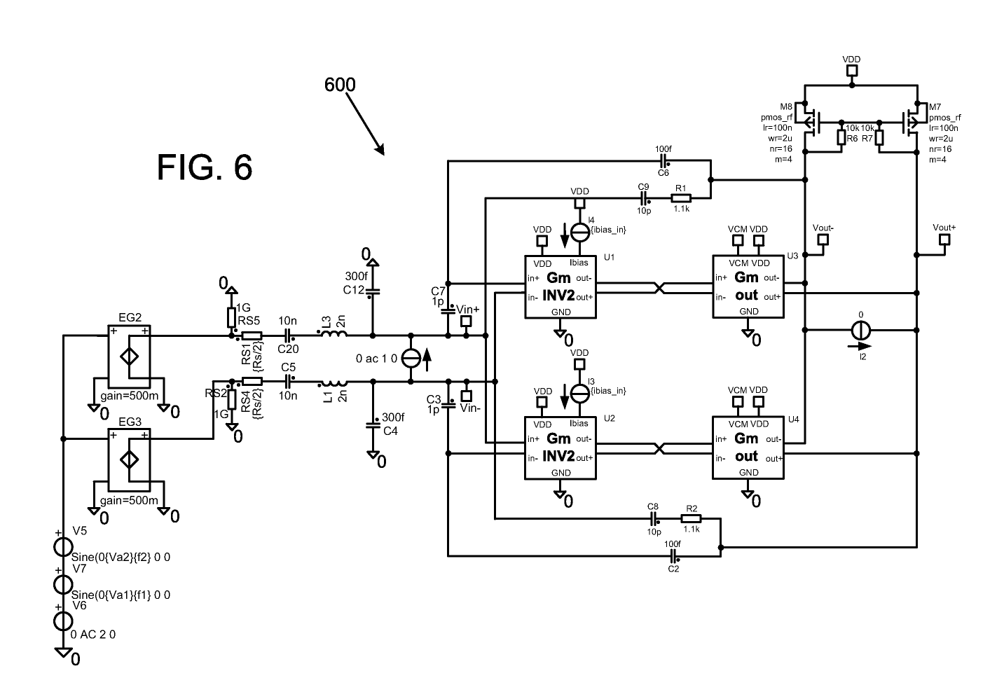

FIG. 6 shows trans-conductance amplifier topology 600 that have been implemented with a two stage amplifier that generates a gm of more than 100 mS. The trans-conductances can be implemented as two equal differential paths as illustrated by gm_{—}_{^{inv2}} and gm_{—}_{^{out}}. The load resistor R3 may be defined as the parallel combination of all resistors at the output. The input of the input amplifier may be nullified in the amplifier topology 300 but this is achieved only with the feedback network and the input signal to the amplifier and not by any high loop gain. In other words, the input of the two amplifiers gm_{—}_{^{inv2}} becomes zero (nullified). With reference to the upper amplifier gm_{—}_{^{inv2}}, a current flows from the source (resistor RS1) to the positive input of the amplifier (Vᵢₙ₊). Most of this current flows through the resistor R1 and determines the output voltage of the amplifier, i.e. the negative output (Vₒᵤₜ₋). The positive input of the upper gm_{—}_{^{inv2}} may by voltage division between the capacitors C6 and C7 obtain the same value as the voltage at the negative input of the amplifier (Vᵢₙ₋). Since Vᵢₙ₋ is also connected to the negative input of the upper gm_{—}_{^{ubv2}}, the input voltage of gm_{—}_{^{Inv2}} becomes zero—it is zeroed out. A very important feature of the present invention is that this is achieved without requiring a high loop gain. The lower amplifier gm_inv2 operates in the same way as the upper amplifier but with opposite signs.

When the input voltage of the first amplifier is nullified, the active devices (i.e. the transistors) have only small signals to handle which is good for linearity etc. Therefore, the same benefits that are achieved in amplifiers with feedback and high loop gain can be achieved without requiring a high loop gain. Since a high loop gain cannot be realized at higher frequencies, the amplifier topology of the present invention is ideal for achieving feedback-like properties also at higher frequencies.

While the present invention has been described in accordance with preferred compositions and embodiments, it is to be understood that certain substitutions and alterations may be made thereto without departing from the spirit and scope of the following claims.

1. A method of using an amplifier, comprising:
providing an amplifier having a first loop interacting with a second loop, the amplifier having an input signal,
providing a feedback signal to the amplifier, and the first loop and the second loop interacting with the input signal to nullify the feedback signal.

2. The method of claim 1 wherein the method further comprises the first loop and the second loop creating a loop gain that is dependent on feedback components of the amplifier.

3. The method of claim 2 wherein the method further comprises the loop gain being further defined by a ratio between gains in a forward path.

4. The method of claim 1 wherein the method further comprises the first loop cooperating with the second loop to nullify the feedback signal.

5. The method of claim 4 wherein the method further comprises creating a loop gain not exceeding 3 when the amplifier operating at frequencies exceeding 1 GHz.

6. The method of claim 2 wherein the method further comprises the loop gain being substantially independent of any bias current in the amplifier.
